(19) United States
(12) Patent Application Publication
(10) Pub. No.: US 2005/0232347 A1
(43) Pub. Date: Oct. 20, 2005

(54) Apparatus and method for noise enhancement reduction in an adaptive equalizer

(75) Inventor: Chiao-Chih Chang, Taipei City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Mediatek Incorporation

(21) Appl. No.: 11/102,944

(22) Filed: Apr. 11, 2005

Related U.S. Application Data
(60) Provisional application No. 60/562,485, filed on Apr. 15, 2004.

(51) Int. Cl. H03K 5/159

(52) U.S. Cl. 375/232

(57) ABSTRACT

A method for noise enhancement reduction in an adaptive equalizer comprising a plurality of filter tap cells having respective coefficients and tap data values. First, a step size is determined based on a norm value of an i^{th} parameter of an estimated channel response. The coefficient of the i^{th} filter tap cell is updated based on the step size, an error signal, and the tap data value of the i^{th} filter tap cell. The step size is a non-decreasing stepwise function of the norm value of the i^{th}parameter of the estimated channel response. An adaptive equalizer performing the described method is also provided.

The current application is supported by the provisional patent application No. 60/562485 filed on Apr. 15, 2004.

### BACKGROUND

The invention relates to adaptive equalizers, and in particular, to a method capable of achieving noise enhancement reduction in an adaptive equalizer.

As is well known, in addition to being corrupted by noise, the transmitted signal is also subject to channel distortions and distortions caused by multipath interference. Consequently, an adaptive equalizer is generally used to compensate for these effects. FIG. 1 shows a conventional adaptive equalizer diagram. The adaptive equalizer 200 comprises a forward equalizer (FE) 202 and a decision feedback equalizer (DFE) 206. An input signal r(n) is provided to the FE 202, and the output therefrom is added to the output from the DFE 206 in an adder 208 to generate the output signal y(n). The decision unit 203 generates an decision signal d(n) based on the output signal y(n), which acts as an estimate of the original transmitted value of the current output signal y(n) of the adaptive equalizer 200. The decision signal d(n) is then fed back to the DEF 206. As an example, the decision unit 203 could be a “slicer”, which “slices” the output signal of the equalizer unit. The term “slice” refers to the process of taking the allowed symbol value that is nearest to that of the output signal y(n).

The error estimator 207 generates an error signal e (n) based on the decision signal d(n) and the output signal y(n). Typically, the error signal e(n) is the difference between the decision signal d(n) and the output signal y(n). The coefficient updater 205 is used to recursively update the coefficients of the adaptive equalizer 200, including the coefficients of the FE 202 and the DFE 206 based on the error signal e(n) by using the well-known Least Mean-Squared (LMS) algorithm. In a typical LMS algorithm, the coefficient vector C(n) of the adaptive equalizer 200 is updated using the following formula:
y(n)=C^{T}(n)X(n) (1)
e(n)=d(n)−y(n) (2)
C(n)=C(n−1)+μ·e(n)·X(n) (3)
where C(n)=[c₀(n), c₁(n), . . . , c_{K}(n)] is the coefficient vector of the adaptive equalizer 200 with K being the number of coefficients of the adaptive equalizer 200, wherein [c₀(n), c₁(n), . . . , c_{M-1}(n)] is the vector of the FE 202 with M being an integer less than K and [c_{M}(n), c_{M+1}(n), . . . , c_{K}(n)] is the vector of the DFE 206, C^{T}(n) is the transpose of the coefficient vector C(n).

X(n)=[x₀(n), x₁(n), . . . , x_{K}(n)] is the tap data vector of the adaptive equalizer wherein [x₀(n), x₁(n), . . . , x_{M-1}(n)] is the tap data vector of the FE 202 and [x_{M}(n) X_{M+1}(n), . . . , x_{K}(n)] is the tap data vector of the DFE 206.
y(n) is the output signal of the adaptive equalizer 200;
d(n) is the output of the decision unit 203;
e(n) is the error signal;
p is a step size;

In many applications, including digital television systems, the communication channel is corrupted with sparsely separated echoes. In such case, the adaptive equalizer at receiver side, after adaptation settling time, will have only few non-zero valued equalizer coefficients and most of the equalizer coefficients are close to zero value. Only those non-zero valued coefficients contribute to the equalization to perform channel echo cancellation.

FIG. 2(a) shows a channel response having two echoes within a specific echo distance (measured by time). FIG. 2(b) and (c) shows the equalizer coefficients at different times. By employing the LMS algorithm, the equalizer coefficients are recursively updated to approximate the channel response of the transmission channel. As shown in FIG. 2(b) and (c), two major coefficients, which correspond to the echoes of the transmission channel and reveal substantially non-zero values, are formed. And the remaining equalizer coefficients are all minor coefficients, which have values close to zero and flicker randomly as shown in FIG. 2(b) and (c). The variations of these minor coefficients contribute excessive noise, causing inefficient convergence. This is referred to as noise enhancement. The situation will become even worse if the number of the equalizer coefficients is needed to be large enough to cover the maximal possible long-delayed echo. Therefore, it is desired to reduce the noise resulting from the variations of these minor coefficients such that the performance of the adaptive equalizer can be improved accordingly.

### SUMMARY

An embodiment of the invention provides a method for noise enhancement reduction in an adaptive equalizer comprising a plurality of filter tap cells having respective coefficients and tap data values. First, a step size is determined based on a norm value of an i^{th} parameter of an estimated channel response. The coefficient of the i^{th} filter tap cell is updated based on the step size, an error signal, and the tap data value of the i^{th} filter tap cell. The step size is a non-decreasing stepwise function of the norm value of the i^{th} parameter of the estimated channel response.

Another embodiment of the invention provides an adaptive equalizer performing the described method is also provided.

### BRIEF DESCRIPTION OF THE DRAWINGS

The following detailed description, given by way of example and not intended to limit the invention solely to the embodiments described herein, will best be understood in conjunction with the accompanying drawings, in which:

FIG. 1 shows a conventional adaptive equalizer diagram;

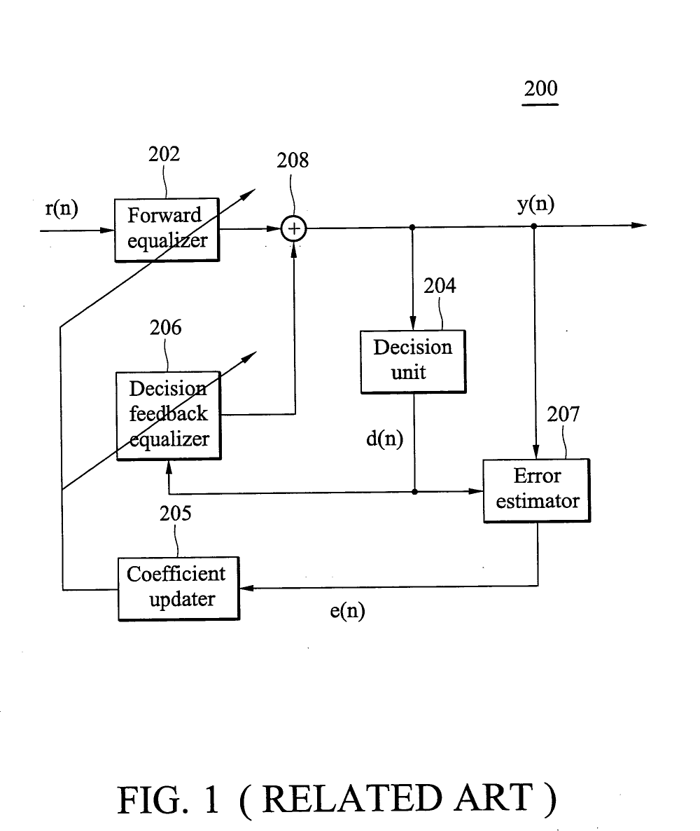

FIG. 2 shows a channel response having two echoes within a specific echo distance (measured by time);

FIG. 3 shows an adaptive equalizer diagram according to an embodiment of the invention;

FIG. 4 shows the stepwise weighting function w(|hᵢ(n)|) versus the norm value of the i^{th} channel parameter |hᵢ(n)|;

FIG. 5 shows another embodiment of the step size calculator 680;

FIG. 6 shows the i^{th} tap filter cell according to an alternative embodiment of the invention;

FIG. 7 shows another way to modify the output signal the of the filter tap cell 410 to achieve noise enhancement reduction; and

FIG. 8 is a flowchart of the coefficient update.

### DETAILED DESCRIPTION OF THE INVENTION

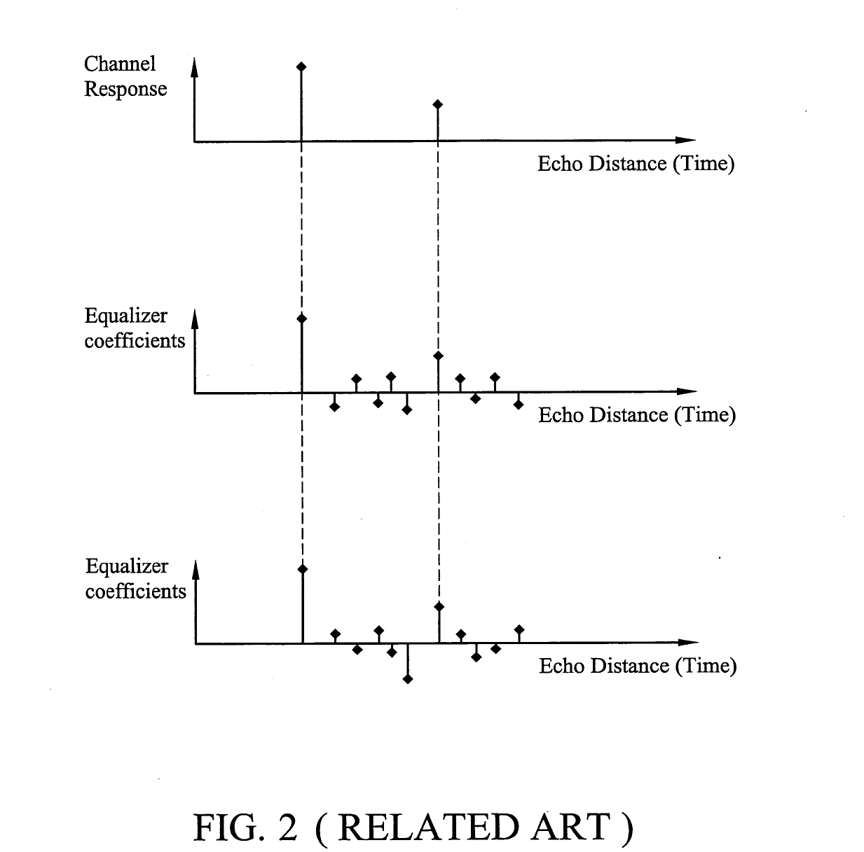

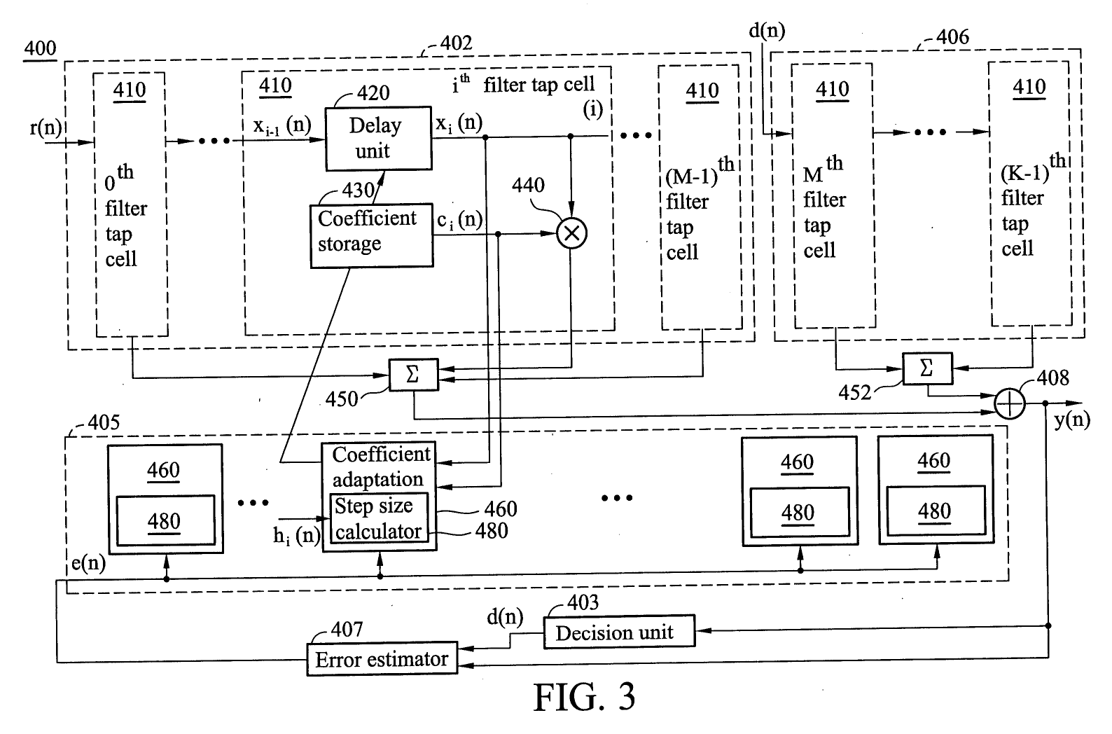

FIG. 3 shows an adaptive equalizer diagram according to an embodiment of the invention. The adaptive equalizer 400 comprises a forward equalizer (FE) 402 and a decision feedback equalizer (DFE) 406, an adder 408, a decision unit 403, an error estimator 407, and a coefficient updater 405. Except the coefficient updater 405, the blocks are the same as those in FIG. 2, and the detailed descriptions are omitted. Both the FE 402 and DFE 406 comprise a number of filter tap cells 410. In this exemplar case, the filter tap cells 410 are numbered from 0 to K−1, where K is an integer corresponding to the implementation of the adaptive equalizer 400, wherein the 0^{th}˜(M−1)^{th} filter tap cells belongs to FE 402 and M^{th}˜(K−1)^{th} ones belong to DFE 406. Note that, the present invention can also be applied an adaptive equalizer having only FE. Each filter tap cell 410 comprises a delay unit 420, a coefficient storage 430, and a multiplier 440. The delay unit 420 in the i^{th} tap cell receives and delays the data tap value xᵢ₋₁(n) of the (i-1)^{th} filter tap cell to obtain the data tap value xᵢ(n) for the present i^{th} filter tap cell. The coefficient storage 430 stores the coefficient cᵢ(n). Note that the input of the delay unit 420 in the first filter tap cell of FE 402 is the input signal r (n), and the input of the delay unit 420 in the first filter tap cell of DFE 406 is the decision signal d(n). The multiplier 440 in the i^{th} filter tap cell is used to multiply the tap data value xᵢ(n) with the coefficient cᵢ(n) The output of the multiplier 440 of each tap cell in FE is sent to a first integration unit 450 for generating the output of the FE. The first integration unit 450 sums the output of each multiplier 440 in FE 402 to generate an output signal of the FE 402. A second integration unit 452 sums the output-of each multiplier 440 in DFE 406 to generate an output signal of the DFE 406.

The coefficient updater 405 comprises a plurality of adaptation units 460, each corresponds to a filter tap. The adaptation unit 460 corresponding to i^{th} tap cell is used to calculate the coefficient cᵢ(n+1) for the next time point n+1 based on cᵢ(n), xᵢ(n), e(n) and hᵢ(n). The coefficient adaptation algorithm, which is capable of achieving noise enhancement reduction according to the present invention, is performed in the adaptation unit 460 in each filter tap cell 410 based on the algorithm:
cᵢ(n+1)=cᵢ(n)+e(n)·xᵢ(n)·μ[|hᵢ(n)|] (4)
where:
cᵢ(n+1) is the coefficient of the iₜₕ filter tap cell at time n+1;
cᵢ(n) is the coefficient of the i^{th} filter tap cell at time n;
e(n) is the error signal at time n;
xᵢ(n) is the tap data value of the iₜₕ filter tap cell at time n;
hᵢ(n) is the i^{th} channel parameter of an estimated channel response h(n) at time n; and
μ[|hᵢ(n)|] denotes the step size that is a non-decreasing stepwise function of a norm value of the iₜₕ channel parameter |hᵢ(n)|.

The step size calculator 480 is used to compute the step size needed in the coefficient adaptation based on the iₜₕ channel parameter hᵢ(n) according to the algorithm.
μ|[hᵢ(n)|]=μ₀·w(|hᵢ(n)|) (5)
where μ₀ is a preset constant and w(|hᵢ(n)|) is a weighting function having value in proportion to the norm value of the i^{th} channel parameter |hᵢ(n)|. According to the present invention, μ[|hᵢ(n)|] is a non-decreasing stepwise function of a norm value of the i^{th} channel parameter hᵢ(n). Therefore, the step size for updating the i^{th} coefficient is decreased when the corresponding iₜₕ channel parameter has a small amplitude. In other words, variations of these minor coefficients will be suppressed, thereby the noise enhancement reduction is achieved.

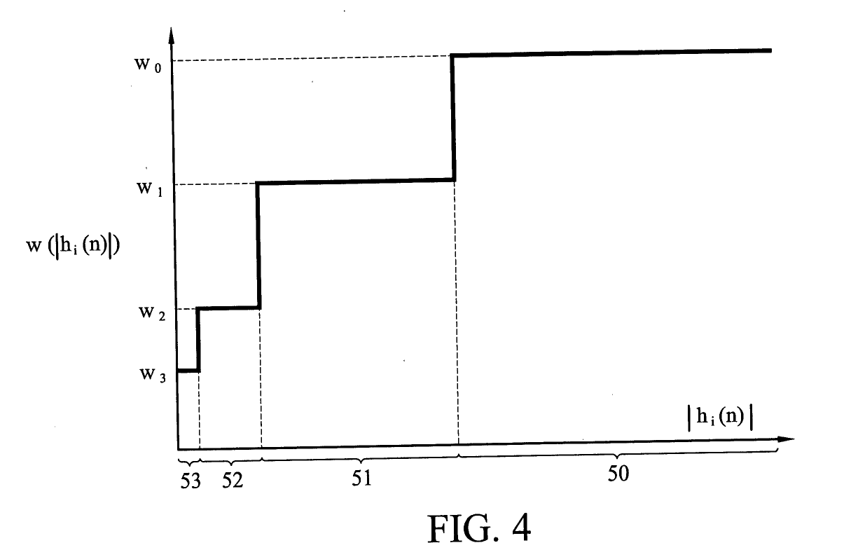

FIG. 4 shows the stepwise weighting function w(|hᵢ(n)|) versus the norm value of the i^{th} channel parameter |hᵢ(n)|. In this example, the norm value of the i^{th} channel parameter |hᵢ(n)| is divided into four regions 50, 51, 52, and 53. If |hᵢ(n)| falls in the region 50, w(|hᵢ(n)|)=w₀. If |hᵢ(n)| falls in the region 51, w(|hᵢ(n)|)=w₁. If |hᵢ(n)| falls in the region 52, w(|hᵢ(n)|)=w₂. If |hᵢ(n)| falls in the region 53, w(|hᵢ(n)|)=w₃. As shown in FIG. 4, w₃<w₂<w₁<w₀. In order to ease the practical implementation, it is preferred that wⱼ=w₀/2^{j}, j=1,2,3.

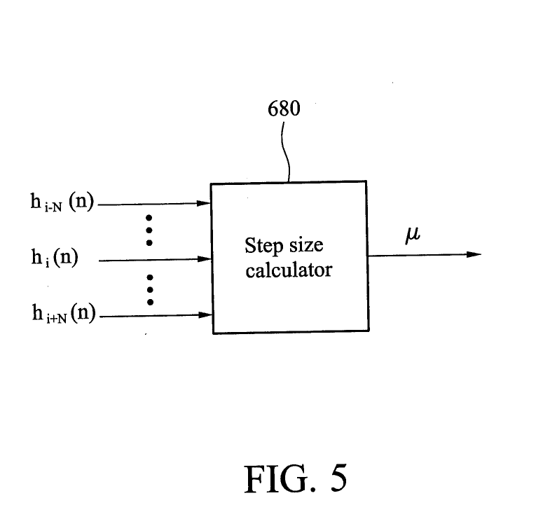

FIG. 5 shows another embodiment of the step size calculator 680. The step size calculator 680 determines a local maximum channel parameter having a local maximum norm value among the i^{th} parameter of the estimated channel response and those parameters adjacent to the i^{th} parameter, and calculates the step size by substituting the norm value of the local maximum channel parameter into the equation (5).

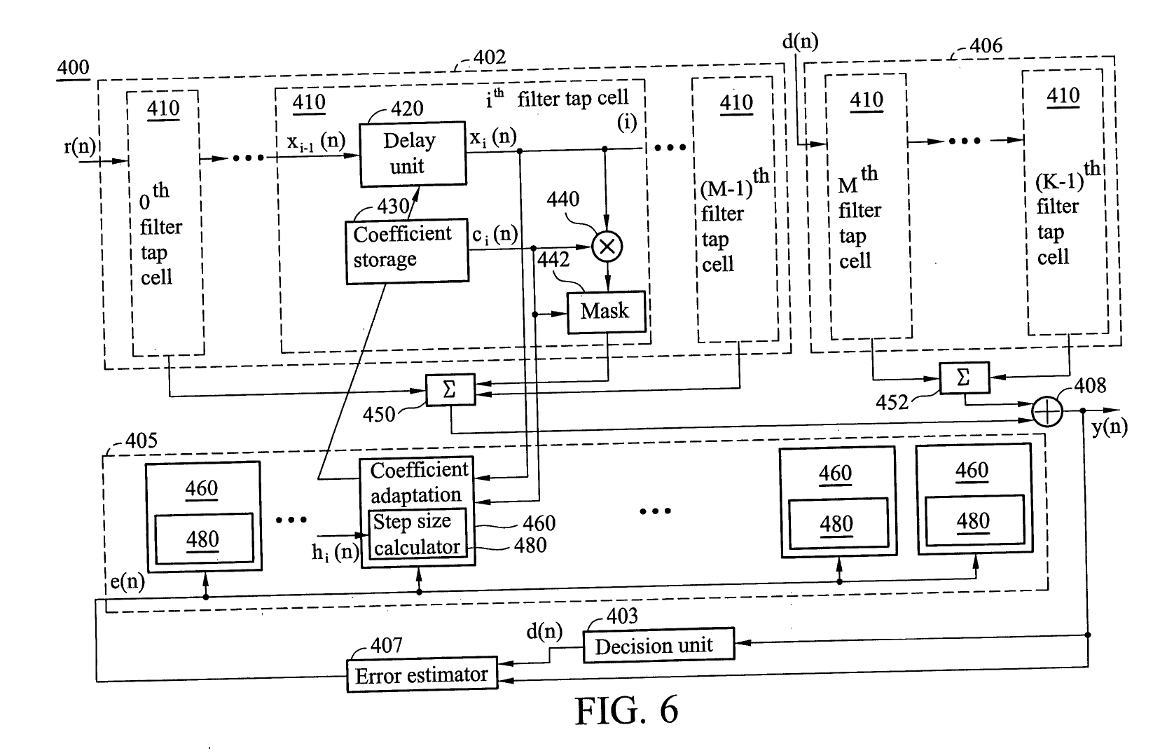

In order to further improve the performance of noise enhancement reduction, the generation of the output signal the of each filter tap cell 410 can be further modified. As shown in FIG. 6, the i^{th} tap filter cell further comprises a mask unit 442. The mask unit 442 sets the output signal of the i^{th} tap filter cell to be zero if a norm value of the coefficient cᵢ(n) is less than a predetermined threshold. Otherwise, the mask unit 442 bypasses the output signal of the i^{th} tap filter. By this way, the variations of these minor coefficients, whose norm values are less than the predetermined threshold, are reduced to zero, thereby the noise enhancement reduction is achieved.

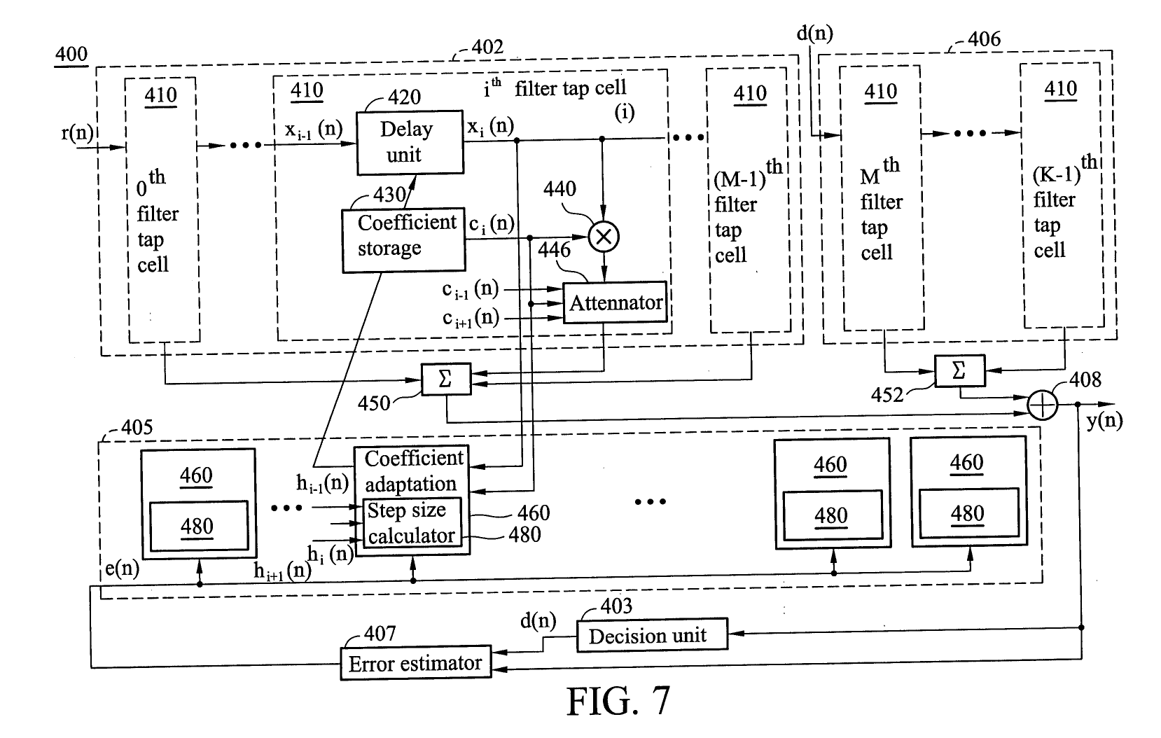

FIG. 7 shows another way to modify the output signal of the filter tap cell 410 to achieve noise enhancement reduction. As shown in FIG. 7, the i^{th} tap filter cell further comprises an attenuator 446 to attenuate the output signal of the i^{th} tap filter cell. If neither the corresponding coefficient nor the coefficient of the tap filter cell adjacent to the i^{th} tap filter cell has its norm value greater than a predetermined threshold, the attenuator 446 will modify the output signal by multiplying the output signal with a preset factor. Otherwise, the attenuator 446 bypasses the output signal. In practical implementation, the preset factor can be ½^{N} where N is a positive integer, or even zero.

Said channel response can be estimated in various ways. For example, the estimated channel response is obtained via a conventional channel estimator. Another way is to estimate the channel response by using the coefficients of tap filter cells. On the other hand, said norm value of the i^{th} parameter of the estimated channel response is referred to as the absolute value of the i^{th} parameter. The other types of norm value, e.g. the square of the absolute value, can also be applicable to the invention.

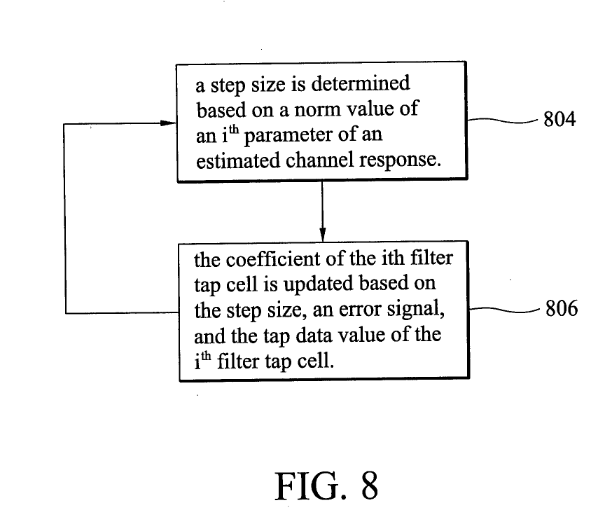

FIG. 8 is a flowchart of the coefficient update. In step 804, a step size is determined based on a norm value of an i^{th} parameter of an estimated channel response. In step 806, the coefficient of the i^{th} filter tap cell is updated based on the step size, an error signal, and the tap data value of the i^{th} filter tap cell. The step size is a non-decreasing stepwise function of the norm value of the i^{th} parameter of the estimated channel response. The procedure returns to step 804 to proceed with determination of the step size for next iteration, thus the procedure loops to converge to a steady state after a period of time. The improved LMS algorithm is capable of reducing the noise enhancement during the process.

While the invention has been described by way of example and in terms of the preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A method for noise enhancement reduction in an adaptive equalizer comprising a plurality of filter tap cells having respective coefficients and tap data values, the method comprising:
determining a step size based on a norm value of an i^{th} parameter of an estimated channel response; and
updating the coefficient of the i^{th} filter tap cell based on the step size, an error signal, and the tap data value of the i^{th} filter tap cell; wherein the step size is a non-decreasing stepwise function of the norm value of the i^{th} parameter of the estimated channel response.

2. The method as claimed in claim 1, wherein the channel response is estimated by the coefficients of tap filter cells, and the i^{th} parameter of the estimated channel response is the coefficient of the i^{th} tap filter cell.

3. The method as claimed in claim 1 wherein the norm value of the i^{th} parameter of the estimated channel response is referred to as the absolute value of the i^{th} parameter.

4. The method as claimed in claim 1, wherein the determination step comprises:
determining a local maximum channel parameter having a local maximum norm value among the i^{th} parameter of the estimated channel response and a plurality of parameters adjacent to the i^{th} parameter; and determining the step size based on the local maximum channel parameter.

5. The method as claimed in claim 1, wherein the updating step comprises:
updating the coefficient of the i^{th} tap filter cell based on the algorithm of the form:
cᵢ(n+1)=cᵢ(n)+e(n)·xᵢ(n)·μ[hᵢ(n)]
where:
cᵢ(n+1) is the coefficient of the i^{th} tap filter cell at time n+1;
cᵢ(n) is the coefficient of the i^{th} tap filter cell at time n;
e(n) is the error signal at time n;
xᵢ(n) is the tap data value of the i^{th} tap filter cell at time n;
hᵢ(n) is the i^{th} channel parameter of the estimated channel response at time n; and
μ[|hᵢ(n)|] denotes the step size, a non-decreasing stepwise function a norm value of the i^{th} channel parameter |hᵢ(n)|.

6. The method as claimed in claim 1, further comprising:
generating an output signal of the i^{th} tap filter cell based on the corresponding coefficient and tap data value if a norm value of the corresponding coefficient is greater than a predetermined threshold, otherwise, setting output signal of the i^{th} tap filter cell to be zero.

7. The method as claimed in claim 1, further comprising:
generating an output signal of the i^{th} tap filter cell based on the corresponding coefficient and tap data value;
attenuating the output signal by multiplying the output signal with a preset factor if neither the corresponding coefficient nor the coefficient of the tap filter cell adjacent to the i^{th} tap filter cell has its norm value greater than a predetermined threshold.

8. The method as claimed in claim 7, wherein the factor equals to ½^{N} where N is a positive integer.

9. The method as claimed in claim 7, wherein the factor equals to zero.

10. An adaptive equalizer capable of achieving noise enhancement reduction, comprising:
a plurality of filter tap cells having respective coefficients and tap data values;
a coefficient adaptation unit for updating the coefficient of an i^{th} filter tap cell based on the step size, an error signal, and the tap data value of the i^{th} filter tap cell wherein the coefficient adaptation unit comprises a step size calculator for determining the step size based on a norm value of an i^{th} parameter of an estimated channel response; wherein the step size is a non-decreasing stepwise function of a norm value of the i^{th} parameter of the estimated channel response.

11. The adaptive equalizer as claimed in claim 10, wherein the channel response is estimated by the coefficients of tap filter cells, and the i^{th} parameter of the estimated channel response is the coefficient of the i^{th} tap filter cell.

12. The adaptive equalizer as claimed in claim 10, wherein the norm value of the i^{th} parameter of the estimated channel response is referred to as the absolute value of the i^{th} parameter.

13. The adaptive equalizer as claimed in claim 10, wherein:
the step size calculator determines a local maximum channel parameter having a local maximum norm value among the i^{th} parameter and a plurality of parameters of the estimated channel response adjacent to the i^{th} parameter, and calculates the step size based on the local maximum channel parameter.

14. The adaptive equalizer as claimed in claim 10, wherein:
the coefficient adaptation unit updates the i^{th} coefficient based on the algorithm of the form:
cᵢ(n+1)=cᵢ(n)+e(n)·r(n−i)·μ[hᵢ(n)]
where:
cᵢ(n+1) is the i^{th} coefficient of the equalizer at time n+1;
cᵢ(n) is the i^{th} coefficient of the equalizer at time n;
e(n) is the error signal at time n;
r(n-i) is the i^{th} delayed version of the input signal at time n;
hᵢ(n) is the i^{th} channel parameter of the estimated channel response at time n; and
μ[hᵢ(n)] denotes the step size, a non-decreasing stepwise function of the i^{th} channel parameter hᵢ(n).

15. The adaptive equalizer as claimed in claim 10, wherein:
the i^{th} tap filter cell comprises a mask unit to set an output signal of the i^{th} tap filter cell to be zero if a norm value of the corresponding coefficient is less than a predetermined threshold.

16. The adaptive equalizer as claimed in claim 10, wherein:
the i^{th} tap filter cell comprises an attenuator to attenuate the output signal of the iₜₕ tap filter cell by multiplying the output signal with a preset factor if neither the corresponding coefficient nor the coefficient of the tap filter cell adjacent to the i^{th} tap filter cell has its norm value greater than a predetermined threshold.

17. The adaptive equalizer as claimed in claim 16, wherein the factor equals to ½^{N} where N is a positive integer.

18. The method as claimed in claim 16, wherein the factor equals to zero.
